(19) United States
(12) Patent Application Publication
(10) Pub. No.: US 2020/0072906 A1
(43) Pub. Date: Mar. 5, 2020

(54) CHARGING GEOMAGNETIC INTERFERENCE RESISTING METHOD AND DEVICE

(71) Applicant: ZTE CORPORATION, Shenzhen, Guangdong (CN)

(72) Inventors: Ting QU, Shenzhen (CN); Cuixiang CHENG, Shenzhen (CN)

(73) Assignee: ZTE Corporation, Shenzhen, Guangdong (CN)

(21) Appl. No.: 16/312,605

(22) PCT Filed: Oct. 25, 2016
(86) PCT No.: PCT/CN2016/103278

§ 371 Date: Jul. 18, 2019

(30) Foreign Application Priority Data
Jun. 21, 2016 (CN) 201610454911.0

(51) Int. Cl. G01R 31/364; G01R 31/392

(52) U.S. Cl. CPC G01R 31/364; G01R 31/045; G01R 31/392

(57) ABSTRACT

“Charging geomagnetic interference resisting method executed by a mobile terminal is provided. The charging geomagnetic interference resisting method includes detecting, by the mobile terminal, a current charging state of the mobile terminal. When the current charging state includes the mobile terminal is being charged, voltage values of multiple preset sampling points are read. A maximum voltage difference value between the multiple preset sampling points are then acquired according to the voltage values of the multiple preset sampling points to obtain a corresponding voltage difference value. A corresponding magnetic field compensation value is also determined based on the voltage difference value. Then, a current magnetic field value of the mobile terminal is read, and the current magnetic field value and the magnetic field compensation are superimposed to acquire a corresponding actual magnetic field value.”

### TECHNICAL FIELD

The disclosure relates to the technical field of charging, and in particular to a charging geomagnetic interference resisting method and device.

### Background

In conventional intelligent terminals, geomagnetism has become a standard configuration for implementing, applications such as an electronic compass and an aided navigation. Since a geomagnetic sensor detects a magnetic field, magnetic devices, such as an earphone, a loudspeaker, and a motor, may affect the geomagnetic sensor. These influences may be avoided by properly arranging position placements of the devices. In a case where the influence cannot be completely avoided, corresponding compensation may be performed. In addition, since currents can generate magnetic fields, any existence of a current also affects the geomagnetic sensor.

In a related technology, a charging process may generate interference to the geomagnetic sensor. The interference results are inconsistent mainly due to reflowing from the ground during charging, and therefore the compensation processing cannot be performed. Because the design of sub-board of many terminals at present causes the reflowing of a charging current during charging, part of the current will flow back through these metal middle frames and metal battery covers, making it difficult to achieve avoidance by arranging the positions. In addition, since this part of the reflow is mainly caused by the influence of contact of a shrapnel, grounding of conductive cloth, and grounding of conductive foam gasket, the influence on the geomagnetic sensor is different in different conditions, and therefore cannot be compensated by software. Since the middle frames of most of the terminals at present are made of metal, more and more full-metal mobile phones are appearing. Further, since the entire terminal is covered with metal, it is almost impossible to find a place on a main board that is not interfered by the reflowing of charging ground.

### SUMMARY

A charging geomagnetic interference resisting method executed by a mobile terminal is provided. The charging geomagnetic interference resisting method includes detecting, by the mobile terminal, a current charging state of the mobile terminal. When the current charging state includes the mobile terminal is being charged, voltage values of multiple preset sampling points are read. A maximum voltage difference value between the multiple preset sampling points are then acquired according to the voltage values of the multiple preset sampling points to obtain a corresponding voltage difference value. A corresponding magnetic field compensation value is also determined based on the voltage difference value. Then, a current magnetic field value of the mobile terminal is read, and the current magnetic field value and the magnetic field compensation are superimposed to acquire a corresponding actual magnetic field value.

### BRIEF DESCRIPTION OF THE DRAWINGS

FIG. 1 is a flow schematic diagram of a charging geomagnetic interference resisting method according to one or more embodiments;

FIG. 2 is an implementation block diagram of a charging geomagnetic interference resisting method one or more embodiments;

FIG. 3 is a flow schematic diagram of acquiring a maximum voltage difference value between sampling points according to voltage values of multiple preset sampling points to obtain a corresponding voltage difference value according to one or more embodiments;

FIG. 4 is a flow schematic diagram of reading voltage values of multiple preset sampling points according to one or more embodiments;

FIG. 5 is a flow schematic diagram of reading a current magnetic field value of a mobile terminal, and superimposing the current magnetic field value and a magnetic field compensation value to acquire a corresponding actual magnetic field value according to one or more embodiments;

FIG. 6 is a flow schematic diagram of a charging geomagnetic interference resisting method according to one or more embodiments;

FIG. 7 is a schematic diagram showing functional modules in a charging geomagnetic interference resisting device according to one or more embodiments; and

FIG. 8 is a schematic diagram showing functional modules in a charging geomagnetic interference resisting device according to one or more embodiments.

The implementation, functional characteristics and advantages of the disclosure will be further described with reference to the accompanying drawings in combination with the embodiments.

### DETAILED DESCRIPTION OF THE EMBODIMENTS

It shall be understood that the specific embodiments described herein are used for illustrating the disclosure, are not intended to be limiting, and are combinable to achieve the technical effects and benefits described herein.

Embodiments herein provide a charging geomagnetic interference resisting method and device, which solves the problems associated with magnetic fields generated by an intelligent terminal in the conventional and related technologies during charging.

A charging geomagnetic interference resisting method provided by an embodiment of the disclosure may be as follows.

A current charging state of a mobile terminal is detected.

In a case where the current charging state is that the mobile terminal is being charged, voltage values of multiple preset sampling points are read.

A maximum voltage difference value between the multiple preset sampling points is acquired according to the voltage values of the multiple preset sampling points to obtain a corresponding voltage difference value.

A corresponding magnetic field compensation value is determined based on the voltage difference value.

A current magnetic field value of the mobile terminal is read, and the current magnetic field value and the magnetic field compensation value are superimposed to acquire a corresponding actual magnetic field value.

In accordance with one or more embodiments, the act that the maximum voltage difference value between the multiple preset sampling points is acquired according to the voltage values of the multiple preset sampling points to obtain the corresponding voltage difference value may include the following acts.

A number of the multiple preset sampling points is determined.

In a case where the number of the multiple preset sampling points is two, the corresponding voltage difference value is determined according to the voltage values of the two preset sampling points.

In a case where the number of the multiple preset sampling points is greater than two, the maximum voltage difference value between the multiple preset sampling points is acquired to obtain the corresponding voltage difference value.

In accordance with one or more embodiments, the act that the voltage values of the multiple preset sampling points are read may include the following acts.

Voltage signals of the multiple preset sampling points are read.

Digital conversion processing is performed on the voltage signals of the multiple preset sampling points to acquire corresponding voltage values.

In accordance with one or more embodiments, the act that the current magnetic field value of the mobile terminal is read, and the current magnetic field value and the magnetic field compensation value are superimposed to acquire the corresponding actual magnetic field value may include the following acts.

The current magnetic field value of the mobile terminal is read and signal amplification processing is performed on the current magnetic field value to acquire a corresponding signal amplification magnetic field value.

The signal amplification magnetic field value and the magnetic field compensation value are superimposed to acquire the corresponding actual magnetic field value.

In accordance with one or more embodiments, after the act that the current charging state of the mobile terminal is detected, the method may further include the following act.

In a case where the current charging state is that the mobile terminal is not being charged, the current magnetic field value of the mobile terminal is directly read.

Another embodiment of the disclosure provides a charging geomagnetic interference resisting device, which may include a detection module, a sampling point reading module, a voltage difference value calculation module, a compensation value calculation module and a superimposing module.

The detection module is configured to detect a current charging state of a mobile terminal.

The sampling point reading module is configured to read voltage values of multiple preset sampling points in a case where the current charging state is that the mobile terminal is being charged.

The voltage difference value calculation module is configured to acquire a maximum voltage difference value between the multiple preset sampling points according to the voltage values of the multiple preset sampling points to obtain a corresponding voltage difference value.

The compensation value calculation module is configured to determine a corresponding magnetic field compensation value based on the voltage difference value.

The superimposing module is configured to read a current magnetic field value of the mobile terminal, and superimpose the current magnetic field value and the magnetic field compensation value to acquire a corresponding actual magnetic field value.

In accordance with one or more embodiments, the voltage difference value calculation module is further configured to determine a number of the multiple preset sampling points; in a case where the number of the multiple preset sampling points is equal to two, determine the corresponding voltage difference value according to the voltage values of the two preset sampling points; and in a case where the number of the multiple preset sampling points is greater than two, acquire the maximum voltage difference value between the multiple preset sampling points to obtain the corresponding voltage difference value.

In accordance with one or more embodiments, the sampling point reading module is further configured to read voltage signals of the multiple preset sampling points; and perform digital conversion processing on the voltage signals of the multiple preset sampling points to acquire corresponding voltage values.

In accordance with one or more embodiments, the superimposing module is further configured to read the current magnetic field value of a mobile terminal and perform signal amplification processing on the current magnetic field value to acquire a corresponding signal amplification magnetic field value; and superimpose the signal amplification magnetic field value and the magnetic field compensation value to acquire the corresponding actual magnetic field value.

In accordance with one or more embodiments, the device may further include a magnetic field value reading module.

The magnetic field value reading module is configured to directly read the current magnetic field value of the mobile terminal in a case where the current charging state is that the mobile terminal is not being charged.

Any of the embodiments herein can be implemented on a computer program product comprising a computer readable storage medium having program instructions implementing charging geomagnetic interference resisting operations embodied therewith. The program instructions are executable by a processor of a mobile terminal.

The embodiments of the disclosure provide a charging geomagnetic interference resisting method and device. In the method, a current charging state of a mobile terminal is detected; in a case where the current charging state is that the mobile terminal is being charged, voltage values of multiple preset sampling points are read; a maximum voltage difference value between the multiple preset sampling points is acquired according to the voltage values of the multiple preset sampling points to obtain a corresponding voltage difference value; a corresponding magnetic field compensation value is acquired by calculation based on the voltage difference value; and a current magnetic field value of the mobile terminal is read, and the current magnetic field value and the magnetic field compensation value are superimposed to acquire a corresponding actual magnetic field value.

A solution adopted in one or more embodiments of the disclosure is described as follows. A current charging state of a mobile terminal is detected; in a case where the current charging state is that the mobile terminal is being charged, voltage values of multiple preset sampling points are read; a maximum voltage difference value between the multiple preset sampling points is acquired according to the voltage values of the multiple preset sampling points to obtain a corresponding voltage difference value; a corresponding magnetic field compensation value is acquired through a determination/calculation based on the voltage difference value; and a current magnetic field value of the mobile terminal is read, and the current magnetic field value and the magnetic field compensation value are superimposed to acquire a corresponding actual magnetic field value.

By virtue of the solution, a problem that a magnetic field generated by an intelligent terminal in conventional and related technologies during charging affects a geomagnetic sensor is solved. Magnetic field value compensation for the intelligent terminal is implemented, and the actual magnetic field value can be acquired to avoid the interference of a charging magnetic field.

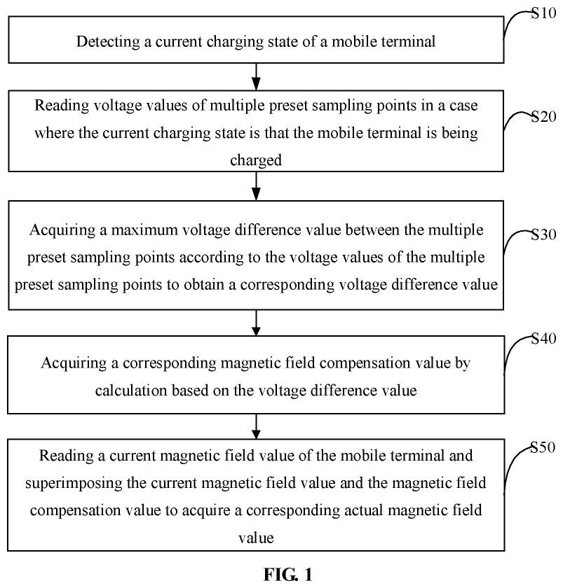

Turning now to FIG. 1, a charging geomagnetic interference resisting method according to one or more embodiments is shown.

At block S10, a current charging state of a mobile terminal is detected.

An executive body for the method in the first embodiment of the disclosure may be a mobile phone or a mobile terminal. The embodiment takes the mobile terminal as an example, and this should not be deemed to exclude other devices or apparatuses that are capable of implementing charging magnetic field interference resisting.

For example, the mobile terminal detects the current charging state of the mobile terminal to check whether the mobile terminal is being charged.

At block S20, in a case where the current charging state is that the mobile terminal is being charged, voltage values of multiple preset sampling points are read.

After the current charging state of the mobile terminal is detected, in a case where the current charging state is that the mobile terminal is being charged, the mobile terminal reads the voltage values of the multiple preset sampling points.

When the mobile terminal is being charged, it is possible to cause interference to a geomagnetic sensor of the mobile terminal due to the reflow of the ground during charging.

The mobile terminal reads voltage values of multiple sampling points in proximity to a geomagnetic sensor of the mobile terminal.

At block S30, a maximum voltage difference value between the multiple preset sampling points is acquired according to the voltage values of the multiple preset sampling points to obtain a corresponding voltage difference value.

For instance, after the voltage values of the multiple preset sampling points are read, the mobile terminal acquires the maximum voltage difference value between the multiple preset sampling points according to the voltage values of the multiple preset sampling points to obtain the corresponding voltage difference value.

The mobile terminal determines/calculates a voltage difference according to the read voltage values of the multiple preset sampling points. In a case where there are only two sampling points, the difference may be directly calculated. In a case where there are more than two sampling points, the voltage difference between two sampling points with maximum difference values is calculated.

At block S40, a corresponding magnetic field compensation value is determined (e.g., acquired by calculation) based on the voltage difference value.

For example, after the maximum voltage difference value between the multiple preset sampling points is acquired according to the voltage values of the multiple preset sampling points to obtain a corresponding voltage difference value, the corresponding magnetic field compensation value is acquired by calculation based on the voltage difference value.

The mobile terminal may determine/calculate the magnetic field compensation value needed by a magnetic field according to the calculated voltage difference value.

Because the size of the magnetic field is in direct proportion to an electric current and therefore is also in direct proportion to a voltage, the magnetic field compensation value for the magnetic field is in linear relation with the voltage difference value.

At block S50, a current magnetic field value of the mobile terminal is read, and the current magnetic field value and the magnetic field compensation value are superimposed to acquire a corresponding actual magnetic field value.

For instance, after the corresponding magnetic field compensation value is acquired by calculation based on the voltage difference value, the mobile terminal reads the current magnetic field value of the mobile terminal and superimposes the current magnetic field value and the magnetic field compensation value to acquire the corresponding actual magnetic field value.

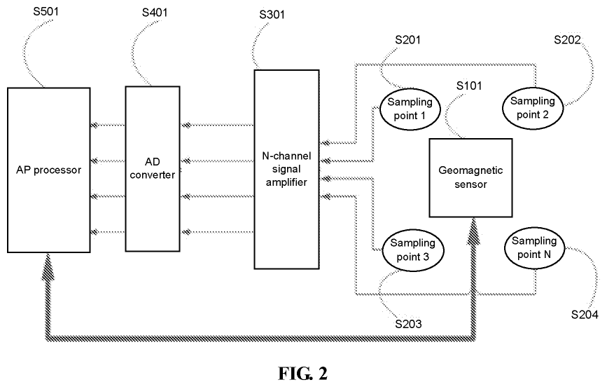

As shown in FIG. 2, the following solution may be adopted according to one or more embodiments.

A mobile terminal is provided with a geomagnetic sensor S101, ground sampling points S201, S202, S203 and S204 arranged in proximity to the geomagnetic sensor, a signal amplifier S301, an Analog-to-Digital (AD) conversion circuit S401 and an Application Processor (AP) S501. The mobile terminal can be an electronic, computer framework comprising and/or employing any number and combination of computing device and networks utilizing various communication technologies, as described herein. The mobile terminal can be easily scalable, extensible, and modular, with the ability to change to different services or reconfigure some features independently of others.

The geomagnetic sensor S101 is configured to receive a signal of a magnetic field around a chip configured to determine the orientation of a direction. The ground sampling points S201, S202, S203 and S204 are configured to sample voltage values on ground signals on the vicinity of a geomagnetic chip during charging process. The signal amplifier S301 is configured to amplify the ground signal to facilitate subsequent AD conversion. The AD converter S401 is configured to convert the received voltage signal into a digital signal and is configured by the AP to process the signal. The AP processor S501 is configured to communicate with the geomagnetic sensor S101, including configuration of the geomagnetic sensor S101 and reading of data of the geomagnetic sensor S101. The AP processor S501 is further configured to receive a digital signal transmitted by the AD converter S401 and converted according to voltages of the multiple preset sampling points, and calculate the voltage difference between the multiple preset sampling points. Because the impedance at two ends of the multiple preset sampling points of a main board is constant in a case that a main-board is determined, the voltage and current at both ends of the multiple preset sampling points are in linear relation, so that the AP processor performs corresponding magnetic field compensation according to the calculated voltage difference, thereby acquiring the correct orientation of the mobile terminal.

Through the above charging geomagnetic interference resisting method provided in one or more embodiments herein, a problem that a magnetic field generated by an intelligent terminal in a related technology during charging affects a geomagnetic sensor can be solved. Magnetic field value compensation for the intelligent terminal can be implemented, and the actual magnetic field value can be acquired to avoid the interference of the charging magnetic field.

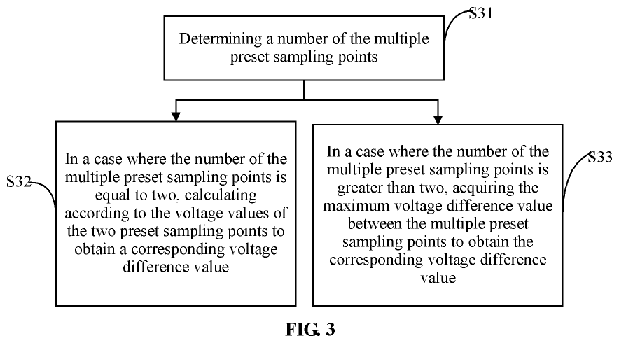

Further, to better avoid the interference of the charging magnetic field, a flow schematic diagram of acquiring a maximum voltage difference value between sampling points according to voltage values of multiple preset sampling points to obtain a corresponding voltage difference value is shown in FIG. 3 according to one or more embodiments is shown.

As an implementation, the abovementioned act S30 may be implemented according to FIG. 3.

At block S31, a number of the multiple preset sampling points is determined.

For example, after the voltage values of the multiple preset sampling points are read, the mobile terminal determines the number of the multiple preset sampling points.

At block S32, in a case where the number of the multiple preset sampling points is equal to two, the corresponding voltage difference value is calculated according to the voltage values of the two preset sampling points.

For instance, after the number of the multiple preset sampling points is determined, in a case where the number of the multiple preset sampling points is equal to two, the mobile terminal performs calculation based on the voltage values of the two preset sampling points to obtain the corresponding voltage difference value.

In a case where two sampling points are to be configured, a suggested solution is to select two sampling points at the vicinity of a diagonal of a geomagnetic chip. For example, one of the two sampling points is close to one side of a charging chip, and the other of the two sampling points is located on a connection line of a grounding point at an outer side of the connection line from the charging chip to the geomagnetic sensor. The purpose of the arrangement of the two sampling points is to find a main path through which the reflowing ground passes. In this case, the voltage difference on the reflowing path is maximized, and the detection accuracy may be improved.

At block S33, in a case where the number of the multiple preset sampling points is greater than two, the maximum voltage difference value between the multiple preset sampling points is acquired to obtain the corresponding voltage difference value.

For instance, after the number of the multiple preset sampling points is determined, in a case where the number of the multiple preset sampling points is greater than two, the mobile terminal acquires the maximum voltage difference value between the multiple preset sampling points to obtain the corresponding voltage difference value.

To enhance the judgment, more detection points (i.e., sampling points) may be arranged around the geomagnetic chip. The detection points may be led to a signal amplifier through a relatively thin ground wire or a 0-ohm resistor in series connection.

Through the charging geomagnetic interference resisting method provided in one or more embodiments, a problem that a magnetic field generated by an intelligent terminal in a related technology during charging affects a geomagnetic sensor can be better solved. Magnetic field value compensation of the intelligent terminal can be implemented, and the actual magnetic field value can be acquired to avoid the interference of the charging magnetic field.

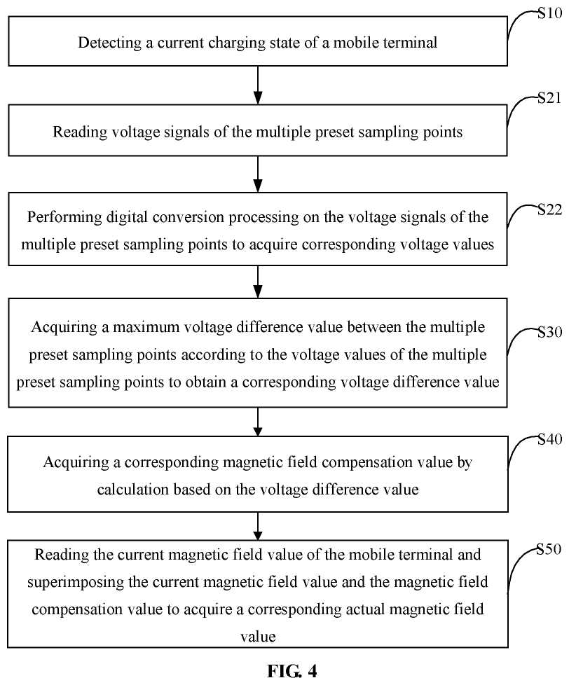

Further, to better avoid the interference of a charging magnetic field, a flow schematic diagram of an act of reading voltage values of the multiple preset sampling points is shown in FIG. 4 according to one or more embodiments.

As an implementation, the above act S20 may be implemented according to FIG. 4.

At block S21, voltage signals of the multiple preset sampling points are read. For instance, after a current charging state of a mobile terminal is detected, the mobile terminal reads the voltage signals of the multiple preset sampling points.

At block S22, digital conversion processing is performed on the voltage signals of the multiple preset sampling points to acquire corresponding voltage values.

For example, after voltage signals of the multiple preset sampling points are read, the mobile terminal performs digital conversion processing on the voltage signals of the multiple preset sampling points to acquire the corresponding voltage values.

Through the charging geomagnetic interference resisting method provided in one or more embodiments, a problem that a magnetic field generated by an intelligent terminal in a related technology during charging affects a geomagnetic sensor can be solved. Magnetic field value compensation for the intelligent terminal can be implemented, and the actual magnetic field value can be acquired to avoid the interference of the charging magnetic field.

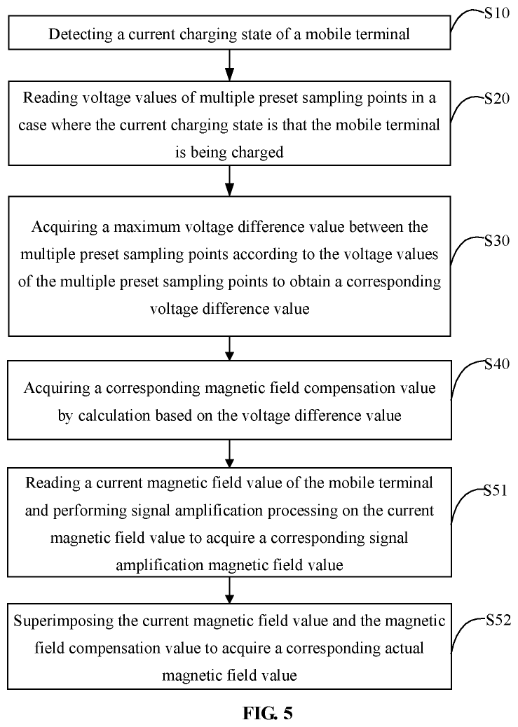

Further, to better avoid the interference of a charging magnetic field, a flow schematic diagram of acts of reading a current magnetic field value of a mobile terminal and superimposing the current magnetic field value and a magnetic field compensation value to acquire a corresponding actual magnetic field value is shown in FIG. 5 according to one or more embodiments.

As an implementation, the above act S50 may be implemented according to FIG. 5.

At block S51, the current magnetic field value of a mobile terminal is read and signal amplification processing is performed on the current magnetic field value to acquire a corresponding signal amplification magnetic field value.

For instance, after the corresponding magnetic field compensation value is acquired by calculation based on the voltage difference value, the mobile terminal reads the current magnetic field value of the mobile terminal and performs signal amplification processing to acquire a corresponding signal amplification magnetic field value, thereby facilitating subsequent AD conversion.

At block S52, the signal amplification magnetic field value and the magnetic field compensation value are superimposed to acquire the corresponding actual magnetic field value.

For example, after the current magnetic field value of the mobile terminal is read and signal amplification processing is performed on the current magnetic field value to acquire the corresponding signal amplification magnetic field value, the mobile terminal superimposes the signal amplification magnetic field value and a magnetic field compensation value to acquire the corresponding actual magnetic field value.

Through the charging geomagnetic interference resisting method provided in one or more embodiments, a problem that a magnetic field generated by an intelligent terminal in a related technology during charging affects a geomagnetic sensor can be solved. Magnetic field value compensation for the intelligent terminal can be implemented, and the actual magnetic field value can be acquired to avoid the interference of the charging magnetic field.

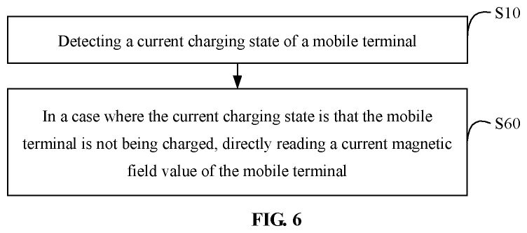

As shown in FIG. 6, a charging geomagnetic interference resisting method is provided (e.g., after the act S10).

At block S60, in a case where the current charging state is that the mobile terminal is not being charged, the current magnetic field value of the mobile terminal is directly read.

For instance, after the current charging state of the mobile terminal is detected, in a case where the current charging state is that the mobile terminal is not being charged, the mobile terminal directly reads a current magnetic field value of the mobile terminal.

When the mobile terminal is not charged, there is no charging magnetic field interference, the current magnetic field value of the mobile terminal can be directly read to serve as an actual magnetic field value.

Through the charging geomagnetic interference resisting method provided in one or more embodiments, a problem that a magnetic field generated by an intelligent terminal in a related technology during charging affects a geomagnetic sensor can be better solved. Magnetic field value compensation for the intelligent terminal can be implemented, and the actual magnetic field value can be acquired to avoid the interference of the charging magnetic field.

Based on the implementation of the abovementioned charging geomagnetic interference resisting method, the disclosure further provides embodiments of a corresponding device.

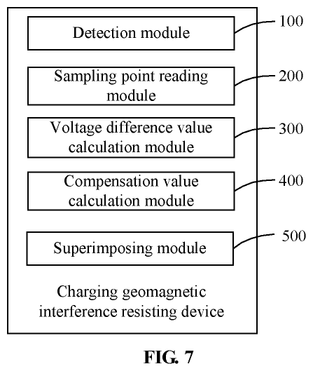

As shown in FIG. 7, a first embodiment of the disclosure provides a charging geomagnetic interference resisting device, which may include a detection module 100, a sampling point reading module 200, a voltage difference value calculation module 300, a compensation value calculation module 400, and a superimposing module 500.

The detection module 100 is configured to detect a current charging state of a mobile terminal.

For instance, the detection module 100 detects the current charging state of the mobile terminal and detects whether the mobile terminal is being charged.

The sampling point reading module 200 is configured to read voltage values of multiple preset sampling points in a case where the current charging state is that the mobile terminal is being charged.

For example, after the current charging state of the mobile terminal is detected, in a case where the current charging state is that the mobile terminal is being charged, the sampling point reading module 200 reads the voltage values of the multiple preset sampling points.

When the mobile terminal is being charged, it is possible to cause interference to a geomagnetic sensor of the mobile terminal due to the reflowing of the ground during charging.

The mobile terminal reads the voltage values of multiple sampling points in proximity to the geomagnetic sensor of the mobile terminal.

The voltage difference value calculation module 300 is configured to acquire a maximum voltage difference value between the multiple preset sampling points according to the voltage values of the multiple preset sampling points to obtain a corresponding voltage difference value.

For instance, after the voltage values of the multiple preset sampling points are read, the voltage difference value calculation module 300 is configured to acquire the maximum voltage difference value between the multiple preset sampling points according to the voltage values of the multiple preset sampling points to obtain a corresponding voltage difference value.

The mobile terminal calculates the voltage difference according to the read voltage values of the sampling points. In a case where there are only two sampling points, the difference may be directly calculated. In a case where there are more than two sampling points, the voltage difference between two sampling points with maximum difference values is calculated.

The compensation value calculation module 400 is configured to acquire a corresponding magnetic field compensation value by calculation based on the voltage difference value.

For example, the compensation value calculation module 400 is configured to, after the maximum voltage difference between the multiple preset sampling points is acquired according to the preset voltage values of multiple sampling points to obtain the corresponding voltage difference value, acquire the corresponding magnetic field compensation value by calculation based on the voltage difference value.

The mobile terminal may calculate the magnetic field compensation value needed by a magnetic field according to the calculated voltage difference value.

Because the size of the magnetic field is in direct proportion to an electric current and therefore is also in direct proportion to a voltage, the magnetic field compensation value for the magnetic field is in linear relation with the voltage difference value.

The superimposing module 500 is configured to read a current magnetic field value of the mobile terminal, and superimpose the current magnetic field value and the magnetic field compensation value to acquire a corresponding actual magnetic field value.

For instance, the superimposing module 500 is configured to, after the corresponding magnetic field compensation value is acquired by calculation based on the voltage difference value, read the current magnetic field value of the mobile terminal, and superimpose the current magnetic field value and the magnetic field compensation value to acquire a corresponding actual magnetic field value.

Through the charging geomagnetic interference resisting solution provided in one or more embodiments, a problem that a magnetic field generated by an intelligent terminal in a related technology during charging affects a geomagnetic sensor can be better solved. Magnetic field value compensation for the intelligent terminal can be implemented, acquires the actual magnetic field value and avoids the interference of the charging magnetic field.

Further, in order to better avoid the interference of a charging magnetic field, as an implementation, the abovementioned voltage difference value calculation module 300 is further configured to determine a number of the multiple preset sampling points; in a case where the number of the multiple preset sampling points is equal to two, calculate the corresponding voltage difference value according to the voltage values of the two preset sampling points; and in a case where the number of the multiple preset sampling points is greater than two, acquire the maximum voltage difference value between the multiple preset sampling points to obtain the corresponding voltage difference value.

For instance, after the voltage values of the multiple preset sampling points are read, the mobile terminal determines a number of the multiple preset sampling points.

After the number of the multiple preset sampling points is determined, in a case where the number of the multiple preset sampling points is equal to two, the mobile terminal calculates according to the voltage values of the two preset sampling points to obtain the corresponding voltage difference value.

In a case where two sampling points are to be configured, a suggested solution is to select two sampling points at the vicinity of a diagonal of a geomagnetic chip. For example, one of the two sampling points is close to one side of a charging chip, and the other of the two sampling points is located on a connection line of a grounding point at an outer side of the connection line from the charging chip to the geomagnetic sensor. The purpose of the arrangement of the two sampling points is to find a main path through which the reflowing ground passes. In this case, the voltage difference on the reflowing path is maximized, and the detection accuracy may be improved.

After the number of the multiple preset sampling points is determined, in a case where the number of the multiple preset sampling points is greater than two, the mobile terminal acquires the maximum voltage difference value between the multiple preset sampling points to obtain the corresponding voltage difference value.

In order to enhance the judgment, more detection points (i.e., sampling points) may be arranged around the geomagnetic chip. The detection points may be led to a signal amplifier through a relatively thin ground wire or a 0-ohm resistor in series connection.

Through the charging geomagnetic interference resisting device provided in one or more embodiments, a problem that a magnetic field generated by an intelligent terminal in a related technology during charging affects a geomagnetic sensor can be better solved. Magnetic field value compensation of the intelligent terminal can be implemented, and the actual magnetic field value can be acquired to avoid the interference of the charging magnetic field.

Further, in order to better avoid the interference of a charging magnetic field, as an implementation, the abovementioned sampling point reading module 200 is further configured to read voltage values of multiple preset sampling points, and perform digital conversion processing on the voltage signals of the multiple preset sampling points to acquire corresponding voltage values.

For instance, after the current charging state of the mobile terminal is detected, the mobile terminal reads the voltage signals of the multiple preset sampling points.

After voltage signals of the multiple preset sampling points are read, the mobile terminal performs digital conversion processing on the voltage signals of the multiple preset sampling points to acquire the corresponding voltage values.

Through the charging geomagnetic interference resisting device provided in an embodiment of the disclosure, a problem that a magnetic field generated by an intelligent terminal in a related technology during charging affects a geomagnetic sensor can be better solved. Magnetic field value compensation of the intelligent terminal can be implemented, and the actual magnetic field value can be acquired to avoid the interference of the charging magnetic field.

Further, in order to better avoid the interference of a charging magnetic field, as an implementation, the abovementioned superimposing module 500 is further configured to read a current magnetic field value of a mobile terminal and perform signal amplification processing on the current magnetic field value to acquire a corresponding signal amplification magnetic field value; and superimpose the signal amplification magnetic field value and the magnetic field compensation value to acquire the corresponding actual magnetic field value.

For instance, after the corresponding magnetic field compensation value is acquired by calculation according to a voltage difference value, the mobile terminal reads the current magnetic field value of the mobile terminal and performs signal amplification processing to acquire a corresponding signal amplification magnetic field value, thereby facilitating subsequent AD conversion.

After the current magnetic field value of the mobile terminal is read and signal amplification processing is performed on the current magnetic field value to acquire a corresponding signal amplification magnetic field value, the mobile terminal superimposes the signal amplification magnetic field value and the magnetic field compensation value to acquire the corresponding actual magnetic field value.

Through the charging geomagnetic interference resisting device provided in one or more embodiments, a problem that a magnetic field generated by an intelligent terminal in a related technology during charging affects a geomagnetic sensor can be better solved. Magnetic field value compensation of the intelligent terminal can be implemented, and the actual magnetic field value can be acquired to avoid the interference of the charging magnetic field.

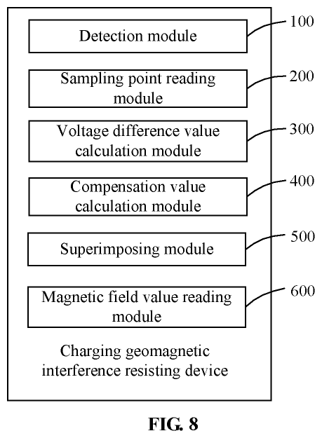

As shown in FIG. 8, a second embodiment of the disclosure provides a charging geomagnetic interference resisting device. On the basis of the above first embodiment, the device may further include a magnetic field value reading module 600.

The magnetic field value reading module 600 is configured to directly read the current magnetic field value of the mobile terminal in a case where the current charging state is that the mobile terminal is not being charged.

For instance, after the current charging state of the mobile terminal is detected, in a case where the current charging state is that the mobile terminal is not being charged, the magnetic field value reading module 600 directly reads the current magnetic field value of the mobile terminal.

When the mobile terminal is not charged, there is no charging magnetic field interference, the current magnetic field value of the mobile terminal can be directly read to serve as an actual magnetic field value.

Through the charging geomagnetic interference resisting device provided in one or more embodiments, a problem that a magnetic field generated by an intelligent terminal in a related technology during charging affects a geomagnetic sensor can be better solved. Magnetic field value compensation for the intelligent terminal can be implemented, and the actual magnetic field value can be acquired to avoid the interference of the charging magnetic field.

The above technical solution provided by the embodiments of the disclosure may be applied to a charging geomagnetic interference resisting process. A current charging state of a mobile terminal is detected. In a case where the current charging state is that the mobile terminal is being charged, voltage values of multiple preset sampling points are read. A maximum voltage difference value between the multiple preset sampling points is acquired according to the voltage values of the multiple preset sampling points to obtain a corresponding voltage difference value. A corresponding magnetic field compensation value is acquired by calculation based on the voltage difference value. A current magnetic field value of the mobile terminal is read, and the current magnetic field value and the magnetic field compensation value are superimposed to acquire a corresponding actual magnetic field value. By virtue of the solution, a problem that a magnetic field generated by an intelligent terminal in a related technology during charging affects a geomagnetic sensor is solved, magnetic field value compensation for the intelligent terminal is implemented, and the actual magnetic field value can be acquired to avoid the interference of the charging magnetic field.

The above is only the exemplary embodiments of the disclosure and is not intended to limit the patent scope of the disclosure. Equivalent structures or equivalent flow transformations made using the specification and the contents of accompanying drawings of the disclosure and directly or indirectly applied to other related technical fields shall fall within the scope of protection of the disclosure.

1. A charging geomagnetic interference resisting method executed by a mobile terminal, the charging geomagnetic interference resisting method comprising:
detecting, by the mobile terminal, a current charging state of the mobile terminal;
when the current charging state comprises the mobile terminal being charged, reading voltage values of multiple preset sampling points;
acquiring a maximum voltage difference value between the multiple preset sampling points according to the voltage values of the multiple preset sampling points to obtain a corresponding voltage difference value,
determining a corresponding magnetic field compensation value based on the voltage difference value;
reading a current magnetic field value of the mobile terminal; and
superimposing the current magnetic field value and the magnetic field compensation value to acquire a corresponding actual magnetic field value.

2. The charging geomagnetic interference resisting method according to claim 1, wherein acquiring the maximum voltage difference value between the multiple preset sampling points according to the voltage values of the multiple preset sampling points to obtain the corresponding voltage difference value comprises:
determining a number of the multiple preset sampling points;
when the number of the multiple preset sampling points is two, determining the corresponding voltage difference according to the voltage values of the two preset sampling points; and
when the number of the multiple preset sampling points is greater than two, acquiring the maximum voltage difference value between the multiple preset sampling points to obtain the corresponding voltage difference value.

3. The charging geomagnetic interference resisting method according to claim 2, wherein reading the voltage values of the multiple preset sampling points comprises:
reading the voltage signals of the multiple preset sampling points; and
performing digital conversion processing on the voltage signals of the multiple preset sampling points to acquire corresponding voltage values.

4. The charging geomagnetic interference resisting method according to claim 3, wherein reading the current magnetic field value of the mobile terminal comprises:
reading the current magnetic field value, and performing signal amplification processing to acquire a corresponding signal amplification magnetic field value.

5. The charging geomagnetic interference resisting method according to claim 1, after detecting the current charging state of the mobile terminal, further comprising:
when the current charging state comprises the mobile terminal being charged, directly reading the current magnetic field value of the mobile terminal.

6. A charging geomagnetic interference resisting device, comprising:
a detection module, configured to detect a current charging state of a mobile terminal;
a sampling point reading module configured to read voltage values of multiple preset sampling points in a case when the current charging state comprises the mobile terminal is being charged;
a voltage difference value calculation module configured to acquire a maximum voltage difference value between the multiple preset sampling points according to the voltage values of the multiple preset sampling points to obtain a corresponding voltage difference value;
a compensation value calculation module; configured to determine a corresponding magnetic field compensation value based on the voltage difference value; and
a superimposing module, configured to read a current magnetic field value of the mobile terminal and superimpose the current magnetic field value and the magnetic field compensation value to acquire a corresponding actual magnetic field value.

7. The charging geomagnetic interference resisting device according to claim 6, wherein the voltage difference value calculation module is further configured to:
determine a number of the multiple preset sampling points;
when the number of the multiple preset sampling points is two, determine the corresponding voltage difference value according to the voltage values of the two preset sampling points; and
when number of the multiple preset sampling points is greater than two, acquire the maximum voltage difference value between the multiple preset sampling points to obtain the corresponding voltage difference value.

8. The charging geomagnetic interference resisting device according to claim 7, wherein the sampling point reading module is further configured to:
read voltage signals of the multiple preset sampling points; and
perform digital conversion processing on the voltage signals of the multiple preset sampling points to acquire corresponding voltage values.

9. The charging geomagnetic interference resisting device according to claim 8, wherein the superimposing module is configured to:
read the current magnetic field value, and performing signal amplification processing to acquire a corresponding signal amplification magnetic field value.

10. The charging geomagnetic interference resisting device according to claim 11, further comprising:
a magnetic field value reading module; configured to directly read the current magnetic field value of the mobile terminal when the current charging state comprises the mobile terminal not being charged.

11. The charging geomagnetic interference resisting method according to claim 3, wherein superimposing the current magnetic field value and the magnetic field compensation value to acquire the corresponding actual magnetic field value comprises:
superimposing the signal amplification magnetic field value and the magnetic field compensation value to acquire the corresponding actual magnetic field value.

12. The charging geomagnetic interference resisting method according to claim 1, wherein the multiple preset sampling points are multiple sampling points in proximity to a geomagnetic sensor of the mobile terminal.

13. The charging geomagnetic interference resisting method according to claim 1, wherein the magnetic field compensation value is in linear relation with the voltage difference value.

14. The charging geomagnetic interference resisting device according to claim 8, wherein the superimposing module is configured to:
superimposing the signal amplification magnetic field value and the magnetic field compensation value to acquire the corresponding actual magnetic field value.

15. The charging geomagnetic interference resisting device according to claim 6, wherein the multiple preset sampling points are multiple sampling points in proximity to a geomagnetic sensor of the mobile terminal.

16. The charging geomagnetic interference resisting device according to claim 6, wherein the magnetic field compensation value is in linear relation with the voltage difference value.

17. A computer program product comprising a computer readable storage medium having program instructions implementing charging geomagnetic interference resisting operations embodied therewith, the program instructions executable by a processor of a mobile terminal to cause the mobile terminal to:
detecting a current charging state of the mobile terminal;
when the current charging state comprises the mobile terminal being charged, reading voltage values of multiple preset sampling points;
acquiring a maximum voltage difference value between the multiple preset sampling points according to the voltage values of the multiple preset sampling points to obtain a corresponding voltage difference value,
determining a corresponding magnetic field compensation value based on the voltage difference value;
reading a current magnetic field value of the mobile terminal; and
superimposing the current magnetic field value and the magnetic field compensation value to acquire a corresponding actual magnetic field value.

18. The computer program product according to claim 17, wherein acquiring the maximum voltage difference value between the multiple preset sampling points according to the voltage values of the multiple preset sampling points to obtain the corresponding voltage difference value comprises:
determining a number of the multiple preset sampling points;
when the number of the multiple preset sampling points is two, determining the corresponding voltage difference according to the voltage values of the two preset sampling points; and
when the number of the multiple preset sampling points is greater than two, acquiring the maximum voltage difference value between the multiple preset sampling points to obtain the corresponding voltage difference value.

19. The computer program product according to claim 18, wherein reading the voltage values of the multiple preset sampling points comprises:
reading the voltage signals of the multiple preset sampling points; and
performing digital conversion processing on the voltage signals of the multiple preset sampling points to acquire corresponding voltage values.

20. The computer program product method according to claim 19, wherein reading the current magnetic field value of the mobile terminal comprises:
reading the current magnetic field value, and performing signal amplification processing to acquire a corresponding signal amplification magnetic field value.
